(19) United States
(12) Patent Application Publication
(10) Pub. No.: US 2007/0158780 A1
(43) Pub. Date: Jul. 12, 2007

(54) Semiconductor integrated circuit device and method of fabricating the same

(75) Inventor: Dong-Ryul Chang, Suwon-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/634,148

(22) Filed: Dec. 6, 2006

(30) Foreign Application Priority Data
Jan. 12, 2006 (KR) 10-2006-0003493

(51) Int. Cl. H01L 29/00

(52) U.S. Cl. 257/500

(57) ABSTRACT

A semiconductor integrated circuit device with higher integration density and a method of fabricating the same are provided. The semiconductor integrated circuit device may include trench isolation regions in a semiconductor substrate that define an active region and a gate pattern that is used for a higher voltage and formed on the active region of the semiconductor substrate. Trench insulating layers may be formed in the semiconductor substrate on and around edges of the gate pattern so as to be able to relieve an electrical field from the gate pattern. The depths of each of the trench insulating layers may be defined according to an operating voltage. Source and drain regions enclose the trench insulating layers and may be formed in the semiconductor substrate on both sides of the gate pattern. Therefore, the semiconductor integrated circuit device may have a higher integration density and may relieve an electrical field from the gate pattern.

### PRIORITY STATEMENT

This application claims priority under 35 USC §119 to Korean Patent Application No. 10-2006-0003493, filed on Jan. 12, 2006, in the Korean Intellectual Property Office (KIPO), the entire contents of which are incorporated herein by reference.

### BACKGROUND

1. Field

Example embodiments relate to a semiconductor integrated circuit device and a method of fabricating the same. Other example embodiments relate to a semiconductor integrated circuit device for increasing integration density and a method of fabricating and operating the same.

2. Description of the Related Art

In the process of fabricating semiconductor integrated circuit devices, power devices, for example, displayed driver integrated circuits (DDI) (e.g. liquid crystal display (LCD) driver integrated circuits (LDI) and/or a lower-voltage (LV) metal oxide semiconductor (MOS) transistor, for example, a MOS field-effect transistor), used for logic operation at a lower voltage and a higher-voltage (HV) MOS transistor (e.g. a MOS field-effect transistor) used for driving a display device, for example, a liquid crystal display (LCD) at a higher voltage, may be formed on a semiconductor substrate at the same time. For this reason, a dual gate oxide layer may be employed. As the integration density of the semiconductor integrated circuit devices increases, a line width may decrease. A trench isolation technique may be inevitably employed for isolation.

The gate oxide layer may be a thermal oxide layer. During a thermal oxidation process for the gate oxide layer in the shallow trench isolation (STI) structure, a thinning phenomenon, in which an oxide layer on the upper edge of a trench becomes thinner, may be generated due to compressive stress which is generated from a silicon substrate while a surface of the silicon substrate and sidewalls of the STI structure are subjected to oxidation, stress of a layer for filling a gap of the STI structure and/or interruption of the flow of an oxidation reaction gas caused by a liner formed in the STI structure.

Such a thinning phenomenon may become more significant when a higher breakdown voltage process is used, for example, when the gate oxide layer is more thickly formed in order to implement the HV MOS transistor. This thinning phenomenon may lead to a double hump and a gate induced drain leakage (GIDL) current may increase due to the concentration of an electrical field in a region where the oxide layer is thinner. A restriction may be imposed on increasing the operating voltage of the HV MOS transistor greater than a specified value (e.g., about 20 V to about 30 V).

In order to fabricate the HV MOS transistor, local oxidation of silicon (LOCOS) may be used to reduce the concentration of the electrical field generated below a gate electrode. By using LOCOS, a thick field oxide layer may be disposed below the gate electrode of the HV MOS transistor, and thus the HV MOS transistor may have a breakdown voltage of about 45 V. When fabricating the HV MOS transistor by employing the isolation process using the STI structure, there may be a proposal to form the isolation region in the STI structure, and to form the gate electrode on the field oxide layers formed by the LOCOS. This is schematically illustrated in FIGS. 1 and 2.

FIG. 1 is a diagram of a conventional HV MOS transistor, and FIG. 2 is a diagram taken along a line A-A′ of FIG. 1. Referring to FIGS. 1 and 2, an active region 108 defined by a trench isolation region 107 may be formed on a specific region of a semiconductor substrate 100. The trench isolation region 107 may have a STI structure formed by using a conventional trench technique. Source and drain regions 104 may be spaced apart from each other by a predetermined or given distance in the active region 108. A channel region (not shown) may be formed between the source and drain regions 104, and a gate electrode 101 may be formed above the channel region. A gate insulating layer 105 may be between the gate electrode 101 and the channel region. Thick field oxide layers 103 may be formed below sides of the gate electrode 101 through LOCOS in order to reduce the concentration of an electrical field. The thick field oxide layers 103 may serve as gate insulating layers. Impurity regions 102, which are implanted with impurity ions at a higher concentration than the source and drain regions 104, may be formed within the source and drain regions 104 where source and drain contacts 109 are to be formed in a subsequent process.

The structure illustrated in FIGS. 1 and 2 may be a field lighted doped drain (FLDD) structure, which is a conventional structure of an HV transistor. In the FLDD structure, a lower concentration of ions may be implanted in advance where the field oxide layers 103 are to be formed, and then an annealing process may be performed before the field oxide layers 103 are formed. Grade junctions 106 may be formed and the field oxide layers 103 may be formed more thickly. Due to the thicker field oxide layers 103, a strong electrical field applied to the gate electrode 101 may be relieved. The FLDD structure may be applied to products requiring a higher voltage of about 20 V to about 50 V.

However, the above-mentioned conventional process may be restricted in that the lower concentration of ions should be implanted before the field oxide layers 103 are formed to increase a junction breakdown voltage below the field oxide layers 103 and may also be relatively complicated because the LOCOS depends on a wet process. It may be very difficult to control the thickness and length of each of the field oxide layers 103 acting as the gate insulating layer using the conventional process. The conventional process for improving the integration density of semiconductor integrated circuit devices may have unfavorable characteristics.

### SUMMARY

Example embodiments provide a semiconductor integrated circuit device with a higher integration density that may be formed without implanting a lower concentration of impurity ions before field oxide layers may be formed and using LOCOS.

Example embodiments also provide a semiconductor integrated circuit device including higher- and lower-voltage MOS transistors and having higher integration density. Example embodiments provide a fabricating method suitable for a semiconductor integrated circuit device.

According to example embodiments, a semiconductor integrated circuit device may include trench isolation regions in a semiconductor substrate that define an active region and a gate pattern formed on the active region of the semiconductor substrate. The semiconductor integrated circuit device may include trench insulating layers formed in the semiconductor substrate on and around edges of the gate pattern so as to relieve an electrical field from the gate pattern. The depths of each of the trench insulating layers may be defined according to an operating voltage.

The semiconductor integrated circuit device may include source and drain regions enclosing the trench insulating layers and formed in the semiconductor substrate on both sides of the gate pattern. The source and drain regions may be each composed of a first impurity region with a lower concentration formed to a greater depth so as to enclose each of the trench insulating layers, and a second impurity region formed in the first impurity region with a higher concentration and a shallower depth than the first impurity region.

According to other example embodiments, there may be a semiconductor integrated circuit device having a higher-voltage metal oxide semiconductor transistor (HVTR) region in which an HVTR may be formed and a lower-voltage metal oxide semiconductor transistor (LVTR) region in which an LVTR may be formed. The HVTR may include a first gate pattern formed on a first active region defined by first trench isolation regions of a semiconductor substrate, trench insulating layers formed on and around edges of the gate pattern so as to relieve an electrical field from the gate pattern, and first source and drain regions enclosing the trench insulating layers and formed in the semiconductor substrate on both sides of the first gate pattern.

The LVTR may include a second gate pattern formed on a second active region defined by second trench isolation regions of the semiconductor substrate, and second source and drain regions on both sides of the second gate pattern. The depths of each of the trench insulating layers may be defined according to an operating voltage and may be greater than the depths of each of the second trench isolation regions, thereby releasing an electrical field from the first gate pattern and allowing for higher integration density.

According to other example embodiments, a method of fabricating a semiconductor integrated circuit device may include forming insulating layers in device isolation trenches to form trench isolation regions in the device isolation trenches defining an active region and forming trench insulating layers in the trench insulating layer trenches. The method may include implanting impurity ions into the active region to form first impurity regions that enclose the trench insulating layers. A gate pattern may be formed on the active region such that both sides thereof are located on the first impurity regions and the trench insulating layers. Impurity ions may be implanted into the active regions on both sides of the gate pattern to form second impurity regions with a higher concentration and a shallower depth than the first impurity regions. The method may also include forming the device isolation trenches in a semiconductor substrate and forming the trench insulating layer trenches in the device isolation trenches.

According to other example embodiments, a method of fabricating a semiconductor integrated circuit device may include forming first trenches for device isolation in a lower-voltage metal oxide semiconductor transistor (LVTR) region of a semiconductor substrate including a higher-voltage metal oxide semiconductor transistor (HVTR) region and the LVTR region. The semiconductor substrate of the HVTR region may be formed with second trenches for device isolation and third trenches for forming trench insulating layers in the second trenches, and the third trenches may have greater depths than the first trenches. Insulating layers may be formed in the first and second trenches to thereby form first and second trench isolation regions to define first and second active regions, respectively and insulating layers may be formed in the third trenches to form trench insulating layers.

The method may include implanting impurity ions into the first active region to form first impurity regions that enclose the trench insulating layers. A gate pattern may be formed on the first active region such that both sides of the gate pattern are located on the first impurity regions and the trench insulating layers, and a second gate pattern for a lower voltage may be formed on the second active region. Impurity ions may be implanted into the second active region to form third impurity regions.

The method may include implanting the impurity ions into the first and second active regions on both sides of the gate patterns to form second impurity regions with a higher concentration and a shallower depth than the first impurity regions within the HVTR region and fourth impurity regions with a higher concentration and a greater depth than the third impurity regions within the LVTR region.

Example embodiments may provide the trench insulating layers under the edges of the first gate pattern without forming the field oxide layers of the HVTR region, so that it may relieve an electrical field from the first gate pattern and simultaneously improve a density of integration. Example embodiments form the trench insulating layers of the HVTR region at a depth greater than the trench isolation regions of the LVTR region, so that it may reduce a voltage applied to the source and drain regions and obtain a higher density of integration.

### BRIEF DESCRIPTION OF THE DRAWINGS

Example embodiments will be more clearly understood from the following detailed description taken in conjunction with the accompanying drawings. FIGS. 1-13 represent non-limiting, example embodiments as described herein.

FIG. 1 is a diagram illustrating a conventional higher voltage (HV) metal oxide semiconductor (MOS) transistor;

FIG. 2 is a diagram taken along lines A-A′ of FIG. 1;

FIGS. 3 and 4 are diagrams illustrating a semiconductor integrated circuit device according to example embodiments;

FIG. 5 is a diagram taken along a line A-A of FIG. 3;

FIG. 6 is a diagram taken along a line B-B of FIG. 4; and

FIGS. 7-13 are diagrams illustrating a method of fabricating a semiconductor integrated circuit device according to example embodiments.

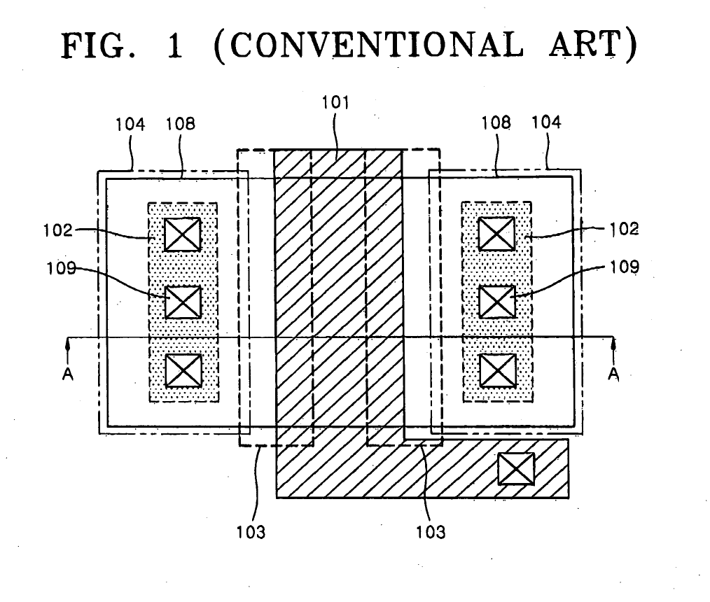

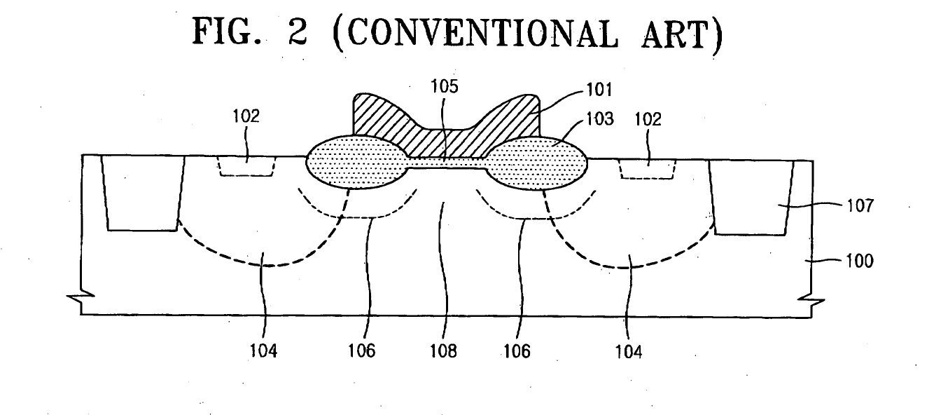

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein. Rather, these example embodiments are provided so that this disclosure will be thorough and complete, and will fully convey the scope of example embodiments to those skilled in the art. In the drawings, the thicknesses of layers and regions are exaggerated for clarity. Like reference numbers refer to like elements throughout the specification.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below.” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements and/or components, but do not preclude the presence or addition of one or more other features, integers, steps, operations, elements, components and/or groups thereof.

Example embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

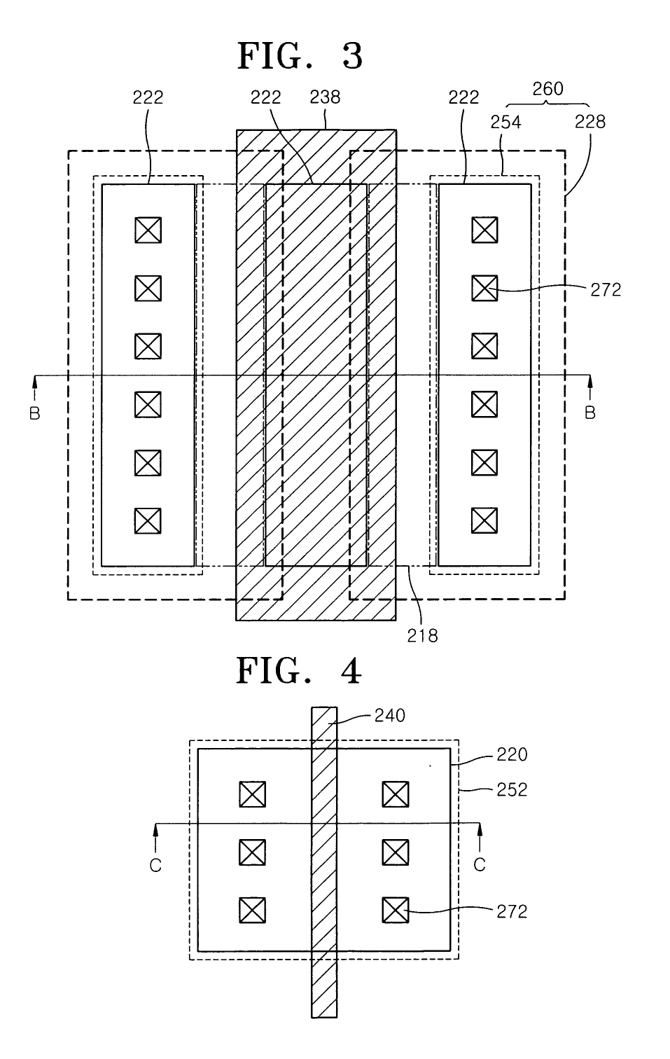

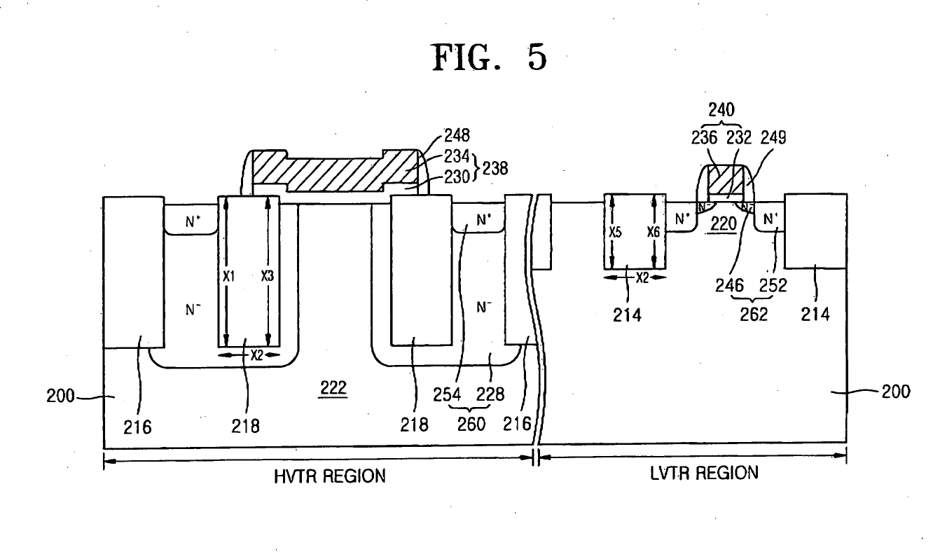

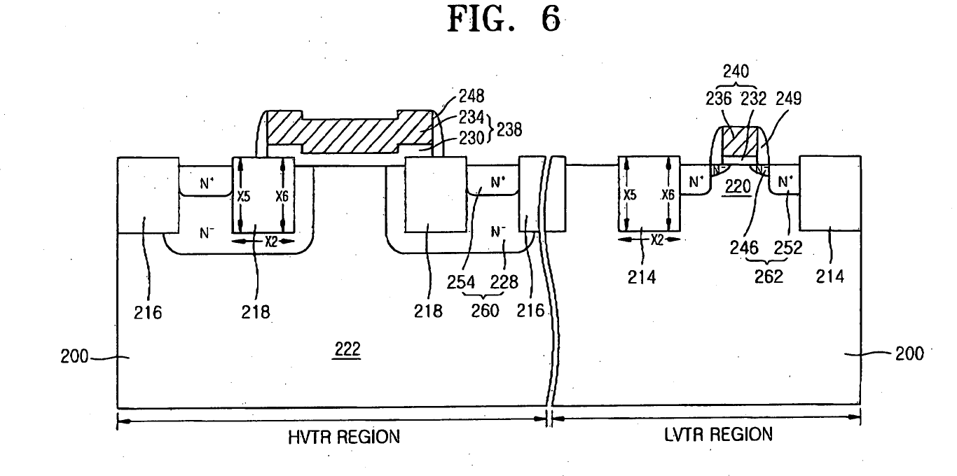

FIGS. 3 and 4 are diagrams illustrating a semiconductor integrated circuit device according to example embodiments, in which FIG. 3 is the layout view of a higher-voltage metal oxide semiconductor (MOS) transistor (HVTR) region, and FIG. 4 is the layer view of a lower-voltage MOS transistor (LVTR) region. FIG. 5 is a diagram illustrating a semiconductor integrated circuit device according to example embodiments, and FIG. 6 is a diagram illustrating a semiconductor integrated circuit device of a comparative example for comparison with FIG. 5. FIGS. 5 and 6 illustrate cross sections taken along lines B-B and C-C of FIGS. 3 and 4, respectively.

Referring to FIGS. 3-6, the semiconductor integrated circuit device may include the HVTR region and the LVTR region. The HVTR region may refer to a region in which a higher-voltage MOS transistor is formed, and the LVTR region may refer to a region in which a lower-voltage MOS transistor is formed.

Example embodiments may be applied to the semiconductor integrated circuit device for driving a displayed driver integrated circuit (DDI) known as a power device (e.g., a liquid crystal display (LCD) driver integrated circuit (LDI)) and having the HVTR and the LVTR for logic operation at lower voltage. The semiconductor integrated circuit device of example embodiments may be applied to any semiconductor integrated circuit device as long as the HVTR of example embodiments may be at least employed. The HVTR may include a MOS transistor operating at higher voltage between about 20 V and about 50 V as set forth above. In the following description, the HVTR and/or LVTR may include an NMOS transistor by way of example, but may alternatively include a PMOS transistor.

Referring to FIGS. 3 and 5, the HVTR region may include a first active region 222 defined by a first trench isolation region 216 on a semiconductor substrate 200, for example, a silicon substrate. The first trench isolation region 216 may have a shallow trench isolation (STI) structure. The first trench isolation region 216 may insulate and may isolate unit MOS transistors. In FIGS. 3 and 5, only one MOS transistor may be illustrated. A first gate pattern 238 for a higher voltage may be located in the middle of the first active region 222. The first gate pattern 238 may be wider than a second gate pattern 240 to be described later. The first gate pattern 238 may be composed of a first gate insulating layer 230 and a first gate electrode 234. The first gate electrode 234 may be a polysilicon layer doped with impurities. First gate spacers 248 may be formed on both sidewalls of the first gate pattern 238.

The semiconductor substrate 200 may have first source and drain regions 260 located on both sides of the first gate pattern 238 for higher voltage. The first source and drain regions 260 may have a double diffused drain (DDD) structure and may include first impurity regions 228 which have lower concentrations. The first source and drain regions may be more deeply formed on both sides of the first gate pattern 238 of the semiconductor substrate 200, and second impurity regions 254 which have higher concentrations may be formed within the first impurity regions 228 of the semiconductor substrate 200 at a shallower depth than the first impurity regions 228. The second impurity regions 254 may include portions where source and drain contacts 272 are to be formed. The first impurity regions 228 may be the first source and drain regions 260.

In example embodiments, when the semiconductor substrate 200 is a P-type silicon substrate, the first impurity regions 228 may be N− impurity regions, while the second impurity regions 254 may be N+ impurity regions. When the semiconductor substrate 200 is an N-type silicon substrate, the conductivities of the first and second impurity regions 228 and 254 may be reversed. The HVTR region of example embodiments may include trench insulating layers 218, each of which is capable of releasing an electrical field from the first gate electrode 234, on both edges of the first gate pattern 238 and within the first impurity regions 228 under the first gate pattern 238. The trench insulating layers 218 may contact the second impurity regions 254, respectively.

The trench insulating layers 218 may have a trench structure and may be formed when the first trench isolation regions 216 are formed. The trench insulating layers 218 may have depths X1 and X3 and a width X2. In example embodiments, the depths X1 and X3 of the trench insulating layers 218 may range from about 0.3 μm to about 3.0 μm. The depths X1 and X3 and the width X2 of each of the trench insulating layers 218 may be equal to those of the first trench isolation region 216.

The trench insulating layers 218 may be enclosed by the first impurity regions 228 constituting the first source and drain regions 260, respectively. The first source and drain regions 260 may be formed in the semiconductor 200 at a greater depth and may enclose the trench insulating layers 218, thereby ensuring reliable operation of the HVTR.

According to the above-mentioned construction of the HVTR of example embodiments, the trench insulating layers 218 may be formed on and around the edges of the first gate pattern 238 without forming the field oxide layers, so that it may be possible to relieve the electrical field from the first gate pattern 238 and simultaneously improve integration density. Example embodiments may overcome the problems caused by the use of the LOCOS. Example embodiments may be formed without the process of implanting a lower concentration of impurity ions under the field oxide layers 103. Also, example embodiments may overcome the difficulty of controlling the thickness and length of each of the field oxide layers 103. The HVTR of example embodiments may have higher integration density.

Referring to FIGS. 4 and 5, the LVTR region of example embodiments may have second trench isolation regions 214 formed in the semiconductor substrate 200 (e.g., the silicon substrate) and a second active region 220 may be defined by the second trench isolation regions 214. The second trench isolation regions 214 may have depths X5 and X6 and a width X2. A second gate pattern 240 may be located in the middle of the second active region 220. The second gate pattern 240 may be composed of a second gate insulating layer 232 and a second gate electrode 236. The second gate insulating layer 232 may be an oxide layer and may be thinner than the first gate insulating layer 230. The second gate electrode 236 may be a polysilicon layer doped with impurities. Second gate spacers 249 may be formed on both sidewalls of the second gate pattern 240, respectively.

Second source and drain regions 262 for a lower voltage may be located in the semiconductor substrate 200 on and around edges of the second gate pattern 240 for a lower voltage. The second source and drain regions 262 may have a light doped drain (LDD) structure, and may be composed of third impurity regions 246 having a lower concentration, which may be formed under the edges of the second gate pattern 240 of semiconductor substrate 200 to a shallower depth, and fourth impurity regions 252 of higher concentration, which contact the third impurity regions 246 and may be formed to a greater depth than the third impurity regions 246. The third impurity regions 246 may include source and drain contacts 272. As in the HVTR of example embodiments, when the semiconductor substrate 200 is a P-type silicon substrate, each of the third impurity regions 246 may be an N− impurity region, while each of the fourth impurity regions 252 may be an N+ impurity region. When the semiconductor substrate 200 is an N-type silicon substrate, the conductivities of the third and fourth impurity regions 246 and 252 may be reversed.

Referring to FIGS. 3, 4, 5 and 6, the depths X1 and X3 of the trench insulating layers 218 of the HVTR region may be greater than the depths X5 and X6 of the second trench isolation regions 214 of the LVTR region. When the depths X1 and X3 of the trench insulating layers 218 are greater, it may be possible to effectively reduce the voltage applied to the first source and drain regions 260 as well as obtain a higher density of integration. The depths of the trench insulating layers 218 in the HVTR region may be varied according to the operating voltage. It may be advantageous for the sum of the depths X1 and X3 and the width X2 of the trench insulating layers 218 to be increased in order to reduce the voltage applied to the first source and drain regions 260. When the width X2 of the trench insulating layers 218 is increased, the pitch of the HVTR may increase, which may make integration more difficult.

When the width X2 of the second trench isolation regions 214 is increased, the pitch of the LVTR may increase, which also may make integration more difficult. When the depths X5 and X6 of the second trench isolation regions 214 are equal to the depths X1 and X3 of the trench insulating layers 218 of the HVTR region, the LVTR region having a higher integration density (or a higher packing density) may undergo increase of the design rules. Only the depths X1 and X3 of the trench insulating layers 218 of the HVTR region may be greater than the depths X5 and X6 of the second trench isolation regions 214 of the LVTR region, so that the voltage applied to the first source and drain regions 260 may be reduced and the integration density may be improved. The depths X1 and X3 of the trench insulating layers 218 of the HVTR region of example embodiments may be varied according to the operating voltage.

In comparing FIG. 5 and FIG. 6, the depths of the trench insulating layers 218 of the HVTR region may be illustrated as being equal to the depths of the second trench isolation regions 214 of the LVTR region in FIG. 6. The structure illustrated in FIG. 6 may provide an improved integration density and simultaneously relieve the electrical field from the first gate pattern 238.

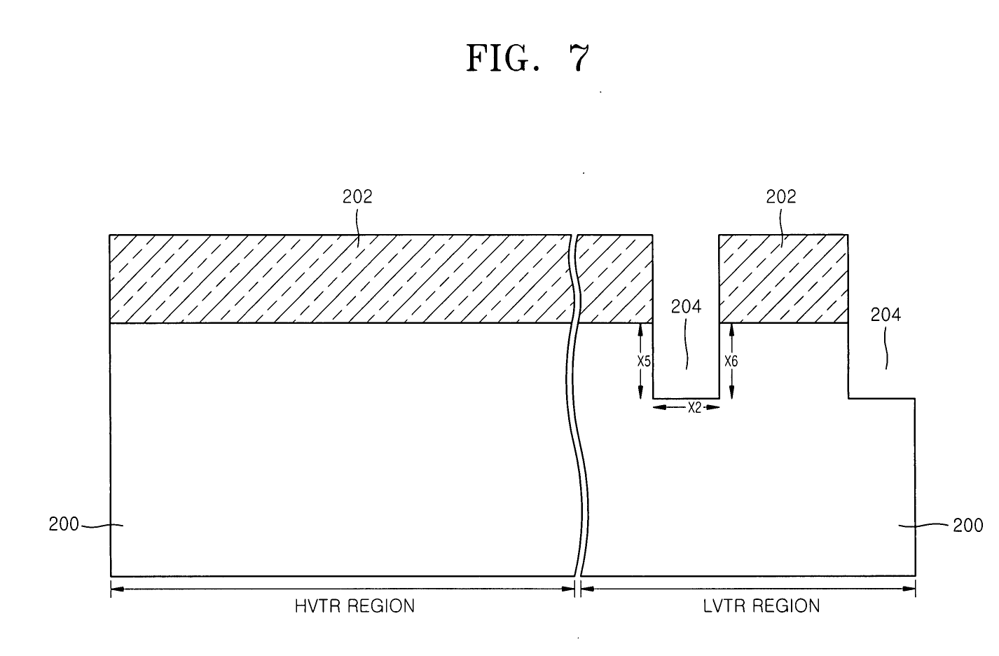

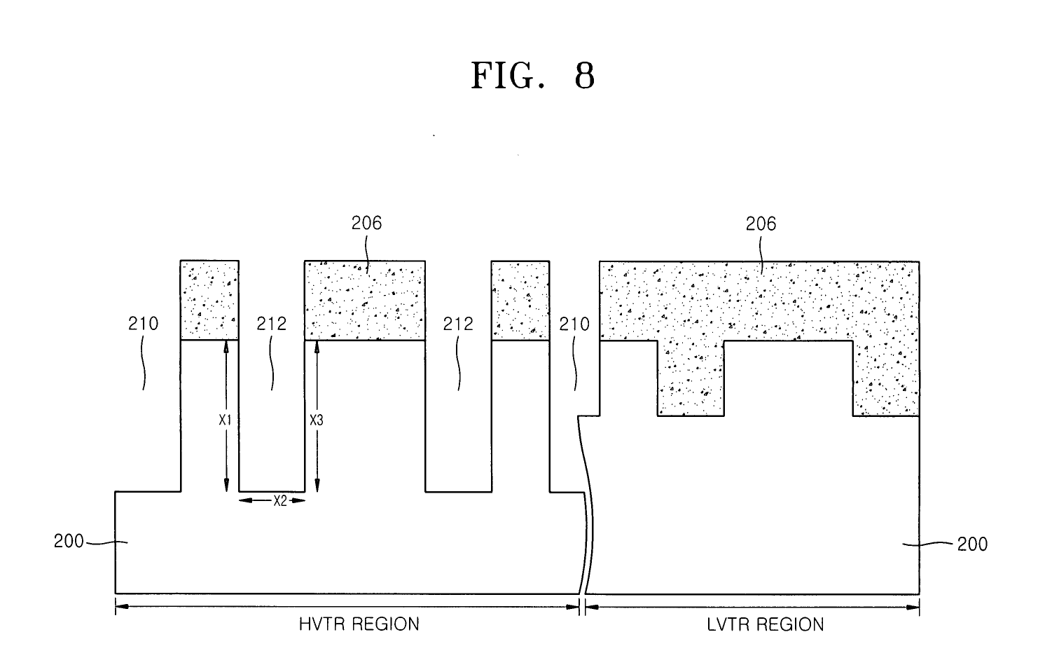

FIGS. 7-13 are diagrams illustrating a method of fabricating a semiconductor integrated circuit device according to example embodiments. The method of fabricating a semiconductor integrated circuit device may include forming an HVTR region and an LVTR region. However, the method may include forming any one of the HVTR and LVTR regions. Referring to FIG. 7, a semiconductor substrate 200, for example, a silicon substrate, including the HVTR and LVTR regions, may be prepared and a first photoresist pattern 202, which partially exposes a surface of the LVTR region, may be formed on the substrate 200. The LVTR region of the semiconductor substrate 200 may be etched using the first photoresist pattern 202 as an etch mask, thereby forming first trenches 204 for device isolation within the LVTR region. The first trenches 204 may become second trench isolation regions 214 in a subsequent process. The first trenches 204 may be formed to depths X5 and X6, and a width X2. Referring to FIG. 8, the first photoresist pattern 202 may be removed, and then a second photoresist pattern 206 partially exposing the HVTR region may be formed. The semiconductor substrate 200 may be etched using the second photoresist pattern 206 as an etch mask, thereby forming second trenches 210 for device isolation and third trenches 212 for forming trench insulating layers within the HVTR region.

The second trenches 210 for the device isolation and the third trenches 212 for forming the trench insulating layers may become first trench isolation regions 216 and may be filled with trench insulating layers 218, respectively, in a subsequent process. The second and third trenches 210 and 212 may be each formed to depths X1 and X3, and to a width X2. Each of the depths X1 and X3 of the second and third trenches 210 and 212 may range from about 0.3 μm to about 3.0 μm. In example embodiments, the second and third trenches 210 and 212 may be formed at the same time and may have equal depths and widths, but their depths and widths may be varied as needed. As set forth above, the second and third trenches 210 and 212 may be formed to a greater depth than the first trenches 204 of the LVTR region. The depths X1 and X3 of the third trenches 212 of the HVTR region may be varied according to the operating voltage.

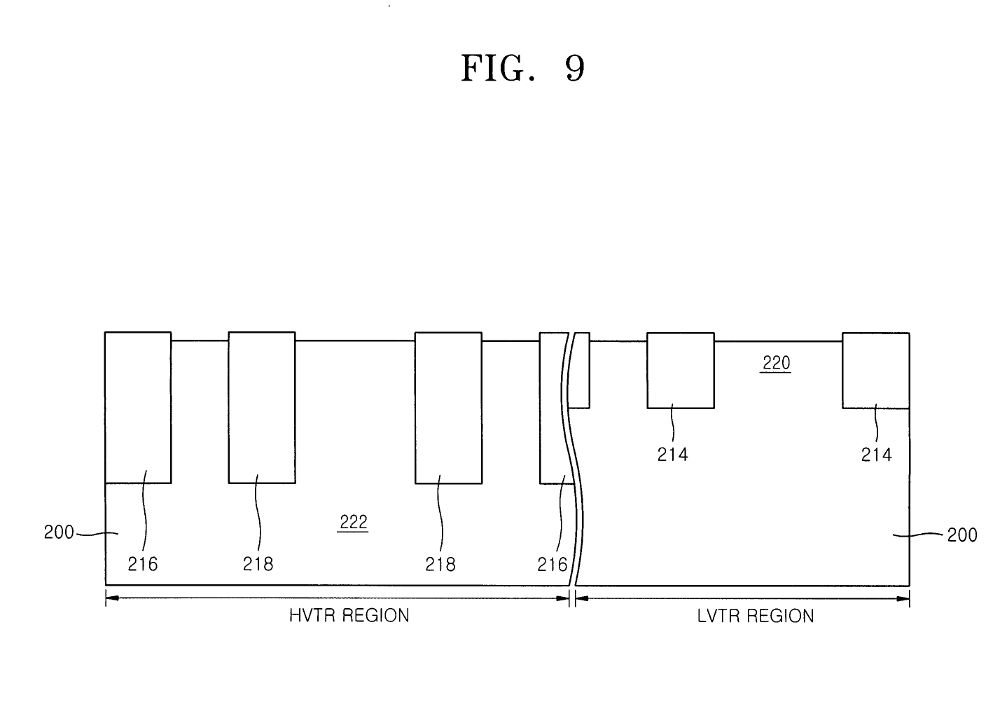

Referring to FIG. 9, the second photoresist pattern 206 may be removed. Insulating layers (e.g., oxide layers) may be filled in the first and second trenches 204 and 210 for the device isolation and the third trenches 212 to form the trench insulating layers and planarized. The first trench isolation regions 216 and the trench insulating layers 218 may be respectively formed in the second trenches 210 and the third trenches 212 within the HVTR region and the second trench isolation regions 214 may be formed in the first trenches 204 within the LVTR region.

The first trench isolation regions 216 of the HVTR region may divide and may insulate unit transistors. A first active region 222 may be defined by the first trench isolation regions 216. The trench insulating layers 218 may be formed within the first active region 222. The first trench isolation regions 216 and the trench insulating layers 218 may be formed using trench technology. The second trench isolation regions 214 of the LVTR region may divide and may insulate unit transistors. A second active region 220 may be defined by the second trench isolation regions 214.

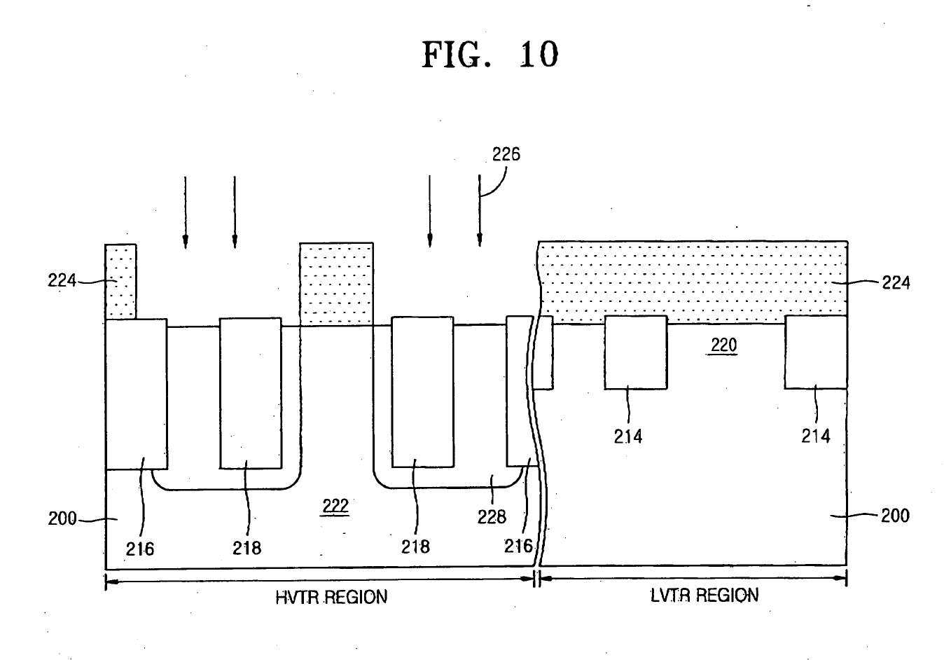

Referring to FIG. 10, a third photoresist pattern 224 may be formed to cover the LVTR region and expose the first active region 222 of the HVTR region. Impurity ions 226 may be implanted into the first active region 222 of the HVTR region using the third photoresist pattern 224 as an ion implantation mask, thereby forming first impurity regions 228. The first impurity regions 228 may be formed to a greater depth so as to enclose the trench insulating layers 218. In example embodiments, the first impurity regions 228 may be formed by implanting phosphorus with an energy of about 100 KeV to 1000 KeV at a dosage of about 10² to about 10⁴ atoms/cm².

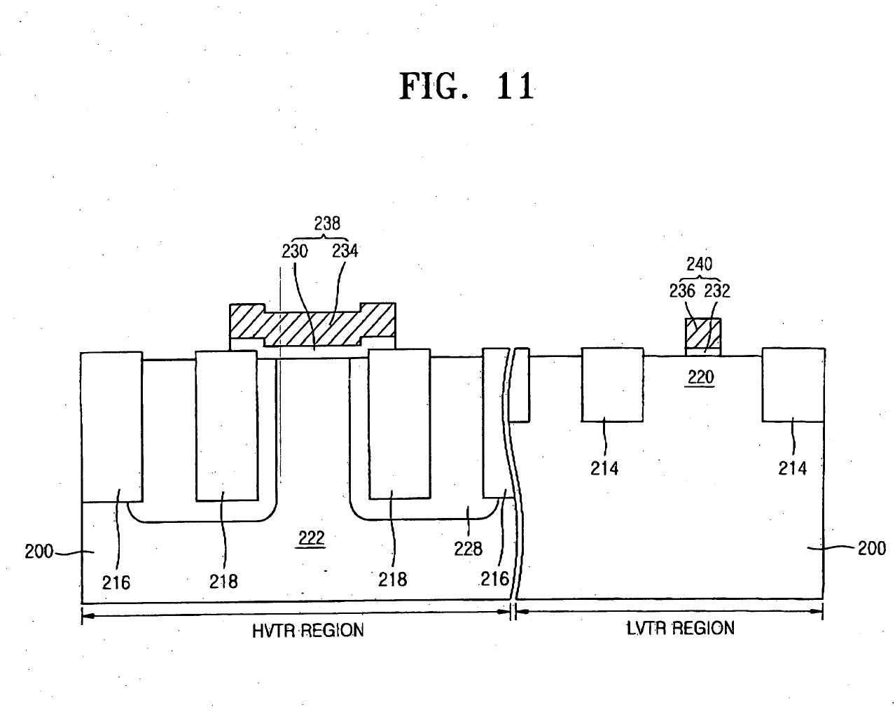

Referring to FIG. 11, the third photoresist pattern 224 may be removed. A first gate pattern 238, which consists of a first gate insulating layer 230 with higher voltage and a first gate electrode 234, may be formed on the first active region 222 and the first impurity regions 228 of the HVTR region. The first gate pattern 238 may be formed on the first active region 222 and the edges of the first gate pattern 238 may be located on the first impurity regions 228 and the trench insulating layers 218. The trench insulating layers 218 may be disposed under the lateral edges of the first gate pattern 238 and the first impurity regions 228 may be disposed at a greater depth and surround the trench insulating layers 218. A second gate pattern 240, which is composed of a second gate insulating layer 232 for a lower voltage and a second gate electrode 236 for a lower voltage, may be formed within the LVTR region.

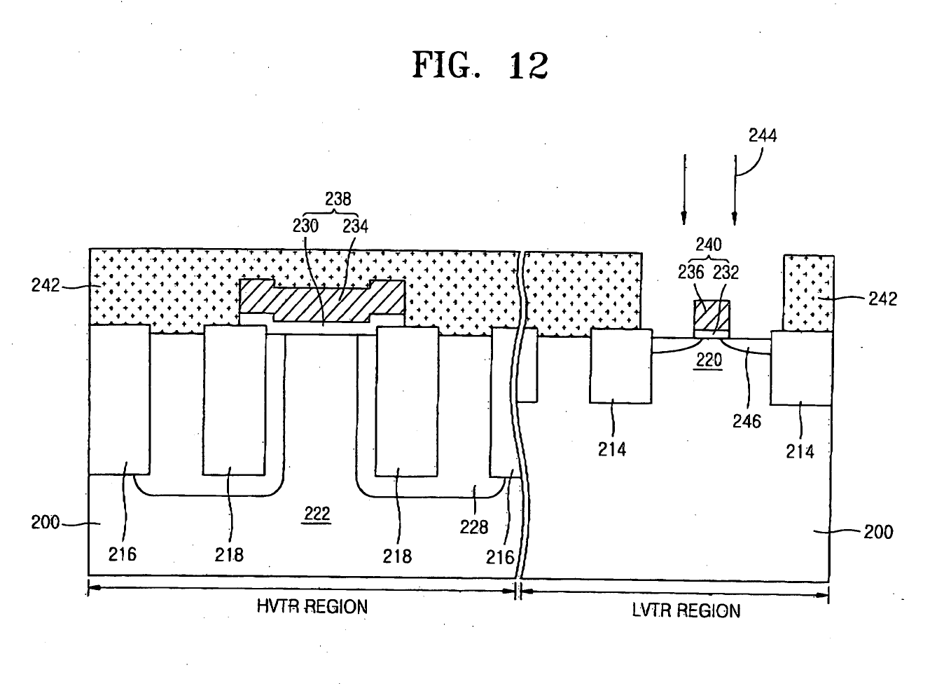

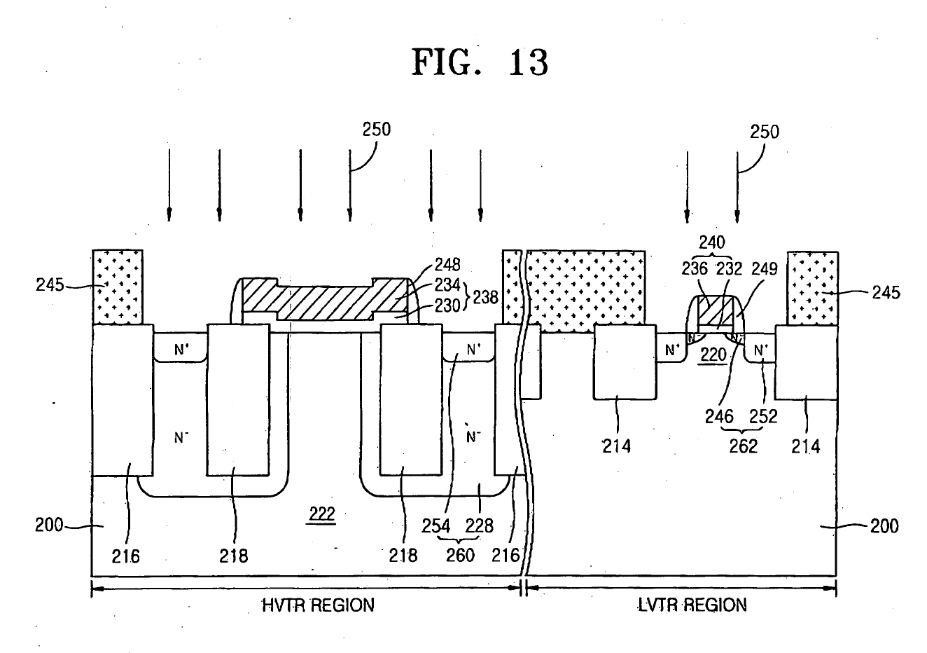

Referring to FIG. 12, a fourth photoresist pattern 242 may be formed to cover the HVTR region and expose part of the LVTR region. Impurity ions 244 may be implanted into the second active region 220 of the LVTR region, thereby forming third impurity regions 246 with a lower concentration. Referring to FIG. 13, the fourth photoresist pattern 242 may be removed, and then first and second gate spacers 248 and 249 may be formed on the sidewalls of the first gate pattern 238 and the second gate pattern 240, respectively. A fifth photoresist pattern 245, that partly covers the HVTR and LVTR regions, may be formed, and then impurity ions 250 may be implanted. Second impurity regions 254 with a higher concentration may be formed within the first impurity regions 228 of the HVTR region at a shallower depth than the first impurity regions 228. Fourth impurity regions 252 may be formed at a higher concentration than and in contact with the third impurity regions 246 of the LVTR region. The first and second impurity regions 228 and 254 may become first source and drain regions 260 of the HVTR region, while the third and fourth impurity regions 246 and 252 may become second source and drain regions of the LVTR region.

As described above, the semiconductor integrated circuit device of example embodiments may include the trench insulating layers under the edges of the first gate pattern without the field oxide layers in the HVTR region, and thus may relieve an electrical field from the first gate pattern and simultaneously have improved integration density. The semiconductor integrated circuit device of example embodiments may include the trench insulating layers of the HVTR region with a greater depth than the trench isolation regions of the LVTR region, and thus may effectively reduce a voltage applied to the source and drain regions and may have a higher integration density. The trench insulating layers of the HVTR region of the semiconductor integrated circuit device of example embodiments may have various depths according to the operating voltage.

While example embodiments have been particularly shown and described with reference to example embodiments thereof, it will be understood by those of ordinary skill in the art that various changes in form and details may be made therein without departing from the spirit and scope of the following claims.

What is claimed is:

1. A semiconductor integrated circuit device comprising:
trench isolation regions in a semiconductor substrate that define an active region;
a gate pattern on the active region of the semiconductor substrate;
trench insulating layers in the semiconductor substrate on and around edges of the gate pattern; and
source and drain regions in the semiconductor substrate on both sides of the gate pattern and enclosing the trench insulating layers, wherein the depths of each of the trench insulating layers is defined according to an operating voltage.

2. The semiconductor integrated circuit device of claim 1, wherein the source and drain regions are each composed of a first impurity region with a lower concentration formed to a greater depth so as to enclose each of the trench insulating layers, and a second impurity region formed in the first impurity region with a higher concentration and a shallower depth than the first impurity region.

3. The semiconductor integrated circuit device of claim 2, wherein the second impurity regions are formed in the semiconductor substrate and contact the trench insulating layers.

4. A semiconductor integrated circuit device comprising:
a higher-voltage metal oxide semiconductor transistor (HVTR) region in which an HVTR is formed, the HVTR including:
a first gate pattern on a first active region defined by first trench isolation regions of a semiconductor substrate;
trench insulating layers on and around edges of the gate pattern so as to relieve an electrical field from the gate pattern; and
first source and drain regions in the semiconductor substrate on both sides of the first gate pattern and enclosing the trench insulating layers; and
a lower-voltage metal oxide semiconductor transistor (LVTR) region in which an LVTR is formed, the LVTR including:
a second gate pattern on a second active region defined by second trench isolation regions of the semiconductor substrate; and
second source and drain regions on both sides of the second gate pattern,
wherein the depths of each of the trench insulating layers is defined according to an operating voltage and are greater than the depths of each of the second trench isolation regions to thereby relieve an electrical field from the first gate pattern and allow for higher integration density.

5. The semiconductor integrated circuit device of claim 4, wherein the first source and drain regions are each composed of a first impurity region with a lower concentration formed to a greater depth so as to enclose each of the trench insulating layers, and a second impurity region formed in the first impurity region with a higher concentration and a shallower depth than the first impurity region.

6. The semiconductor integrated circuit device of claim 5, wherein the second impurity regions are formed in the semiconductor substrate and contact the trench insulating layers.

7. The semiconductor integrated circuit device of claim 5, wherein the depths of each of the trench insulating layers are equal to the depths of each of first trench isolation regions.

8. A method of fabricating a semiconductor integrated circuit device, comprising:
forming insulating layers in device isolation trenches to form trench isolation regions in the device isolation trenches defining an active region and forming trench insulating layers in the trench insulating layer trenches;
implanting impurity ions into the active region to form first impurity regions that enclose the trench insulating layers;
forming a gate pattern on the active region such that both sides of the gate pattern are located on the first impurity regions and the trench insulating layers; and
implanting impurity ions into the active region on both sides of the gate pattern to form second impurity regions with a higher concentration and a shallower depth than the first impurity regions.

9. The method of claim 8, further comprising:
forming the device isolation trenches in a semiconductor substrate and forming the trench insulating layer trenches in the device isolation trenches.

10. The method of claim 8, wherein the depths of the trench insulating layer trenches is defined according to an operating voltage.

11. The method of claim 10, wherein the trench insulating layers are formed in the semiconductor substrate on and around edges of the gate pattern so as to relieve an electrical field from the first gate pattern.

12. A method of fabricating a semiconductor integrated circuit device, comprising:
forming first trenches for device isolation in a lower-voltage metal oxide semiconductor transistor (LVTR) region of a semiconductor substrate including a higher-voltage metal oxide semiconductor transistor (HVTR) region and the LVTR region;
forming second trenches for device isolation in the semiconductor substrate of the HVTR region and third trenches for forming trench insulating layers in the second trenches, the third trenches having greater depths than the first trenches;
forming insulating layers in the first and second trenches to form first and second trench isolation regions defining first and second active regions, respectively, and forming insulating layers in the third trenches to form trench insulating layers;
implanting impurity ions into the first active region to form first impurity regions that enclose the trench insulating layers;
forming a gate pattern on the first active region such that both sides of the gate pattern are located on the first impurity regions and the trench insulating layers, and forming a second gate pattern on the second active region;
implanting impurity ions into the second active region to form third impurity regions; and
implanting impurity ions into the first and second active regions on both sides of the gate patterns to form second impurity regions with a higher concentration and a shallower depth than the first impurity regions within the HVTR region and fourth impurity regions with a higher concentration and a greater depth than the third impurity regions within the LVTR region.

13. The method of claim 12, wherein the depths of the third trenches is defined according to an operating voltage.

14. The method of claim 12, wherein the trench insulating layers are formed in the semiconductor substrate on and around edges of the gate pattern so as to relieve an electrical field from the first gate pattern.

15. The method of claim 12, wherein the first and second impurity regions are first source and drain regions of the HVTR region, and the third and fourth impurity regions are second source and drain regions of the LVTR region.

16. The method of claim 12, wherein the second trenches have the same depth as the third trenches.
